(19) United States
(12) Patent Application Publication
(10) Pub. No.: US 2023/0255027 A1
(43) Pub. Date: Aug. 10, 2023

(54) MEMORY DEVICE AND METHOD OF FABRICATING THE SAME

(71) Applicant: MACRONIX International Co., Ltd., Hsinchu (TW)

(72) Inventor: Jung-Chuan Ting, Hsinchu County (TW)

(73) Assignee: MACRONIX International Co., Ltd., Hsinchu (TW)

(21) Appl. No.: 17/669,016

(22) Filed: Feb. 10, 2022

(51) Int. Cl. H01L 27/11582; H01L 23/48; H01L 27/11519; H01L 27/11556; H01L 27/11565; H01L 27/11573; H01L 27/11526; H01L 23/528

(52) U.S. Cl. CPC H01L 27/11582; H01L 23/481; H01L 27/11519; H01L 27/11556; H01L 27/11565; H01L 27/11573; H01L 27/11526; H01L 23/5283

(57) ABSTRACT

A memory device includes a substrate, a plurality of first memory arrays, a plurality of first bit lines, a first common source plate, and a first through-array contact. The plurality of first memory arrays are disposed in a first plane region of the substrate. The plurality of first bit lines are located between the plurality of first memory arrays and the substrate and are electrically connected to the plurality of first memory arrays. The first common source plate is located above the plurality of first memory arrays and is electrically connected to the plurality of first memory arrays. The first through-array contact is disposed in a first contact region outside the first plane region and is electrically connected to the first common source plate.

### BACKGROUND

### Technical Field

The embodiment of the disclosure relates to a semiconductor device and a method of fabricating the same, and particularly, to a memory device and a method of fabricating the same.

### Description of Related Art

Since a non-volatile memory device (e.g., a flash memory) has the advantage that stored data does not disappear at power-off, it becomes a widely used memory device for a personal computer or other electronics equipment.

Currently, the flash memory array commonly used in the industry includes a NOR flash memory and a NAND flash memory. Since the NAND flash memory has a structure in which memory cells are connected together in series, degree of integration and area utilization thereof are better than those of the NOR flash memory. Thus, the NAND flash memory has been widely used in a variety of electronic products. Besides, to further enhance the degree of integration of the memory device, a three-dimensional NAND flash memory is developed. However, there are still some challenges associated with the three-dimensional NAND flash memory.

### SUMMARY

The disclosure provides a memory device that can reduce the size of a slit to reduce the chip area occupied by the slit.

An embodiment of the disclosure provides a three-dimensional flash memory device including a substrate, a plurality of first memory arrays, a plurality of first bit lines, a first common source plate, and a first through-array contact. The plurality of first memory arrays are located in a first plane region of the substrate. The plurality of first bit lines are located between the plurality of first memory arrays and the substrate and are electrically connected to the plurality of first memory arrays. The first common source plate is located above the plurality of first memory arrays and is electrically connected to the plurality of first memory arrays. The first through-array contact is disposed in a first contact region outside the first plane region and is electrically connected to the first common source plate.

An embodiment of the disclosure provides a three-dimensional flash memory device including a substrate, a circuit structure, a gate stack structure, a plurality of channel pillars, a plurality of charge storage structures, a plurality of bit lines, a common source plate, and a through-array contact. The substrate includes a plane region and a contact region. The plane region includes a plurality of memory array regions. The contact region is located outside the plane region and is adjacent to the plane region. The circuit structure is located on the substrate. The gate stack structure is located above the circuit structure in the plane region. The gate stack structure includes a plurality of gate layers and a plurality of insulating layers alternately stacked with each other. The plurality of channel pillars extend through the gate stack structure. The plurality of charge storage structures are located between the plurality of gate layers and the plurality of channel pillars. The plurality of bit lines are located below the gate stack structure and are electrically connected to bottoms of the plurality of channel pillars and the circuit structure. The common source plate is located above the gate stack structure and is electrically connected to a plurality of top surfaces of the plurality of channel pillars located in the plurality of memory array regions. The through-array contact is disposed in the contact region and is electrically connected to the common source plate and the circuit structure.

An embodiment of the disclosure provides a method of fabricating a three-dimensional flash memory device including the following steps. A substrate including a plane region and a contact region is provided. The plane region includes a plurality of memory array regions, and the contact region is located outside the plane region and is adjacent to the plane region. A circuit structure is formed on the substrate. A plurality of bit lines are formed above the circuit structure and electrically connected to the circuit structure. A plurality of memory arrays are formed on the plurality of bit lines in the plurality of memory array regions and electrically connected to the plurality of bit lines. A common source plate is formed above the plurality of memory arrays and electrically connected to the plurality of memory arrays. A through-array contact is formed in the contact region and electrically connected to the common source plate and the circuit structure.

Based on the above, in the embodiment of the disclosure, the bit lines are formed below the gate stack structure, the common source plate is formed above the gate stack structure, and the through-array contact connecting the common source plate is disposed outside the memory array region and is not disposed in the slit. Therefore, the size of the slit can be reduced, and the chip area occupied by the slit can be reduced.

### BRIEF DESCRIPTION OF THE DRAWINGS

FIG. 1A to FIG. 1C show top views of a plurality of plane regions of a memory device at multiple stages according to an embodiment of the disclosure.

FIG. 2A to FIG. 2C show top views of a memory device in one plane region at multiple stages according to an embodiment of the disclosure.

FIG. 3A to FIG. 3L show schematic cross-sectional views of a fabrication process of a memory device according to an embodiment of the disclosure.

FIG. 4 shows another schematic cross-sectional view of the memory device according to the embodiment of the disclosure.

### DESCRIPTION OF THE EMBODIMENTS

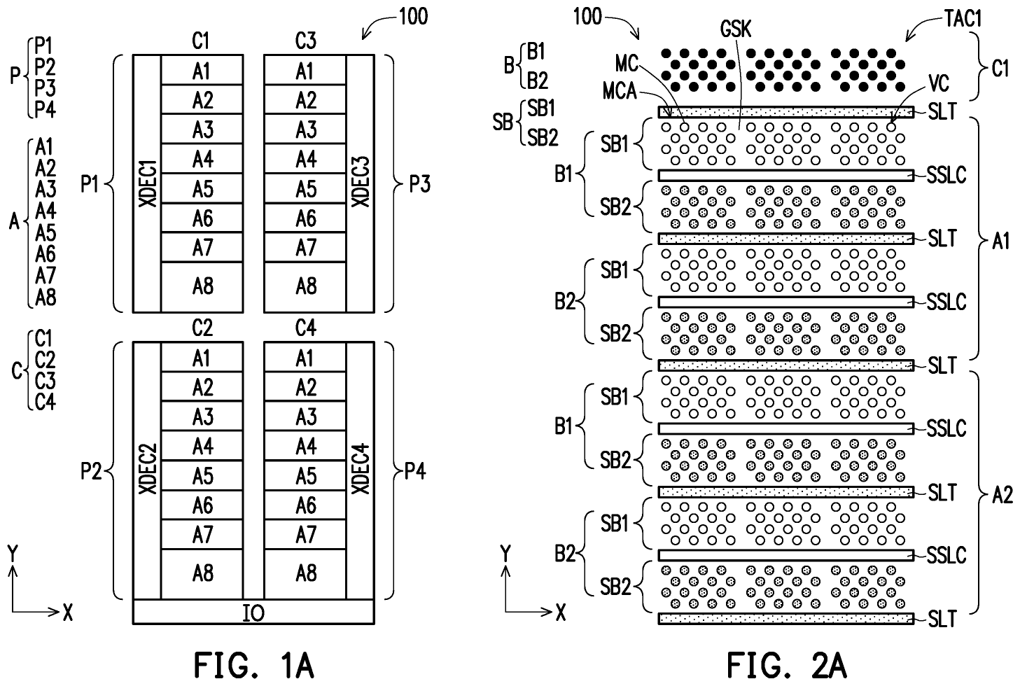

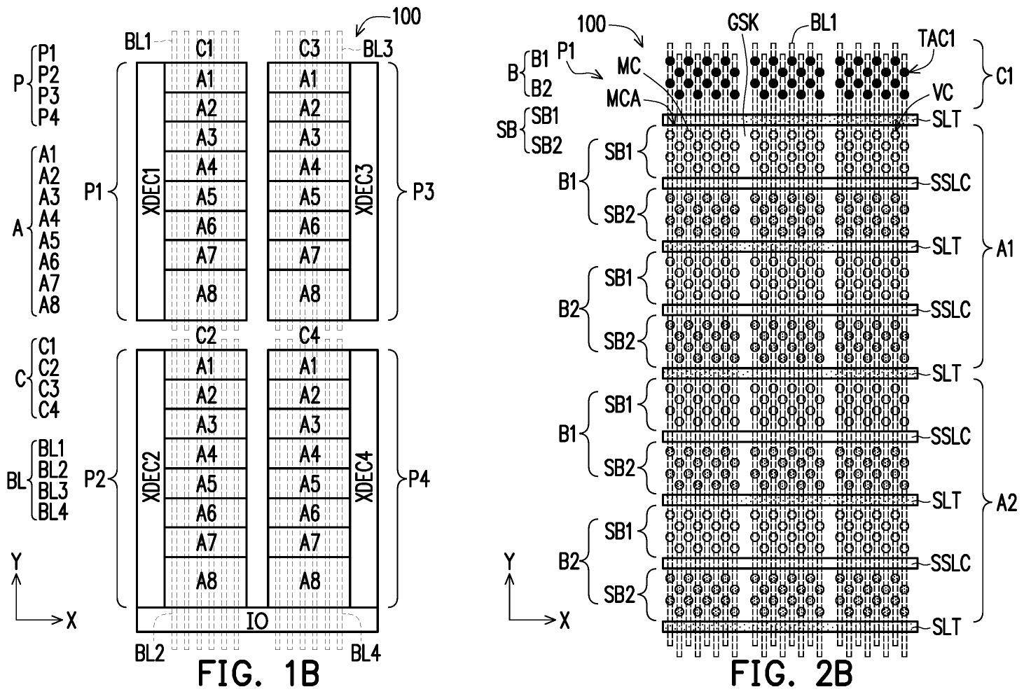

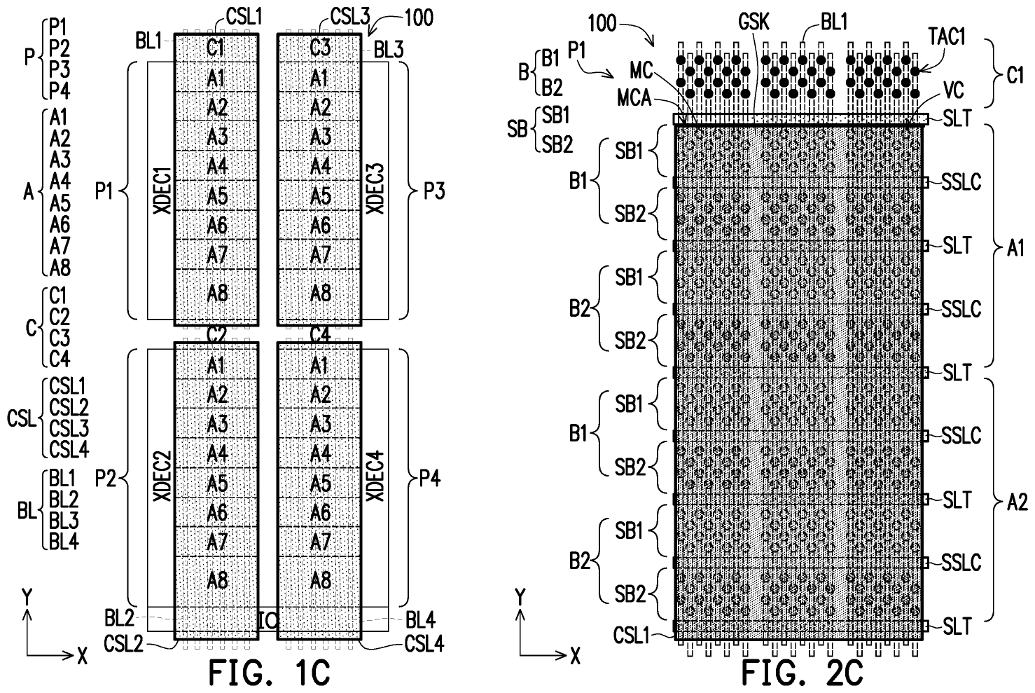

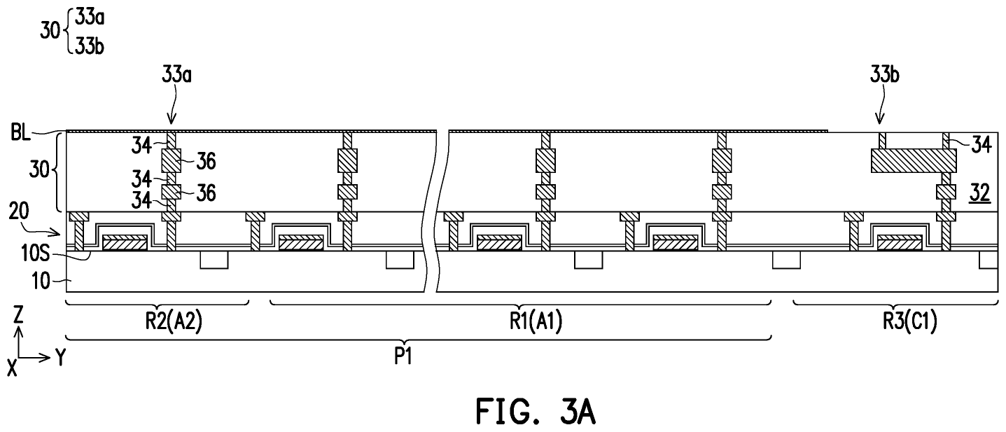

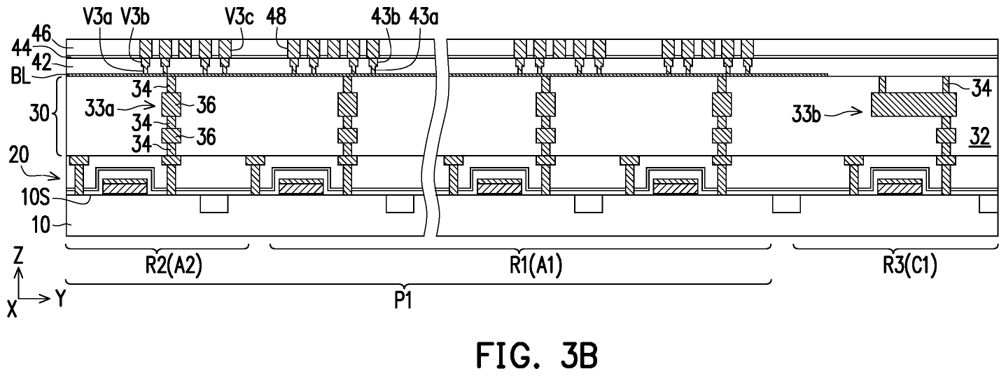

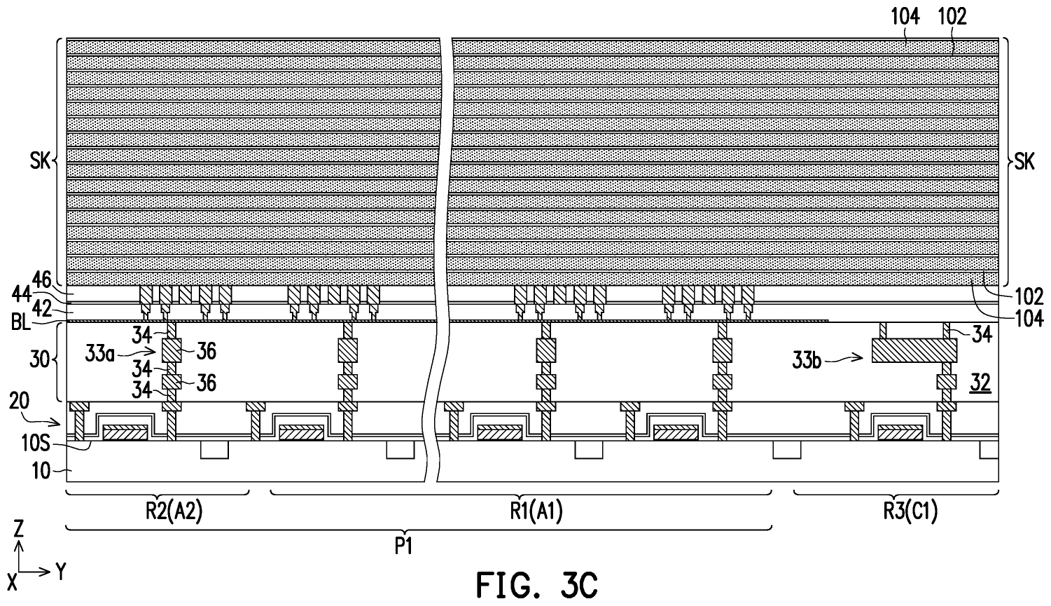

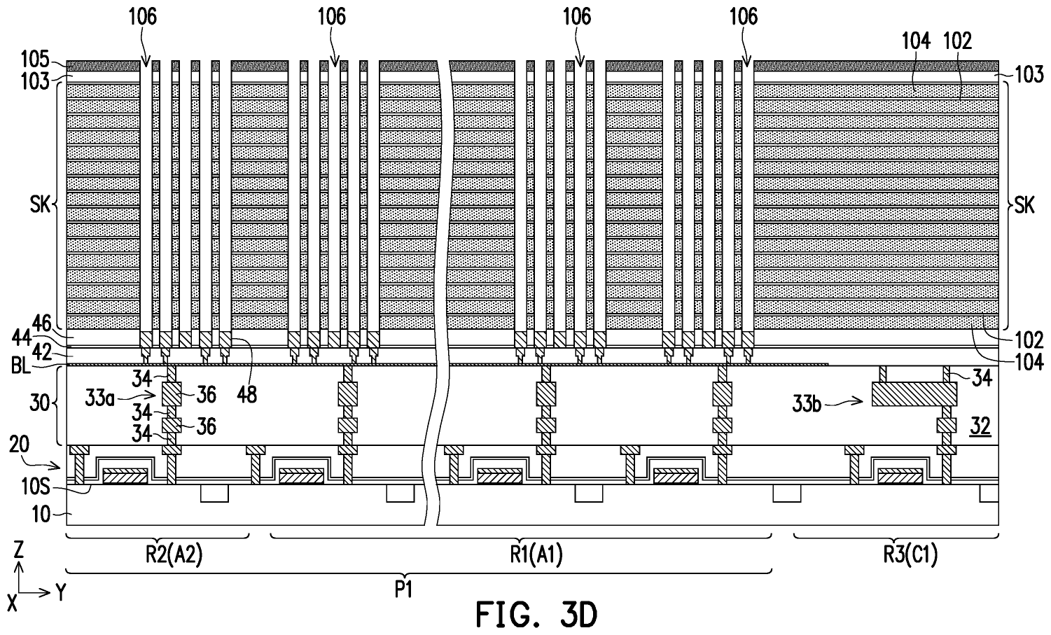

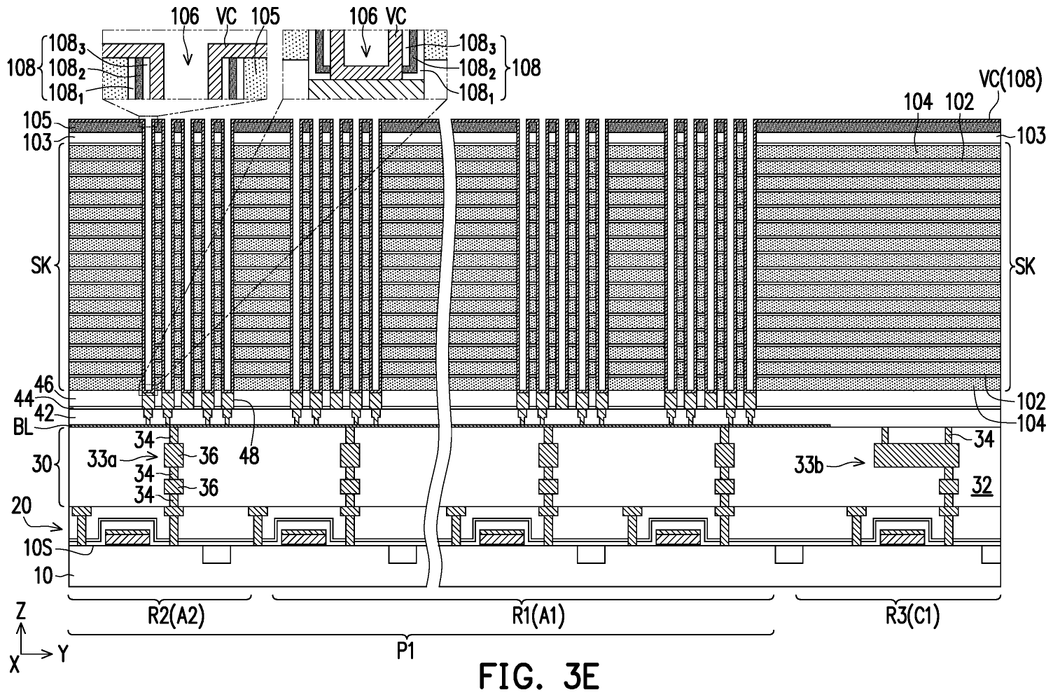

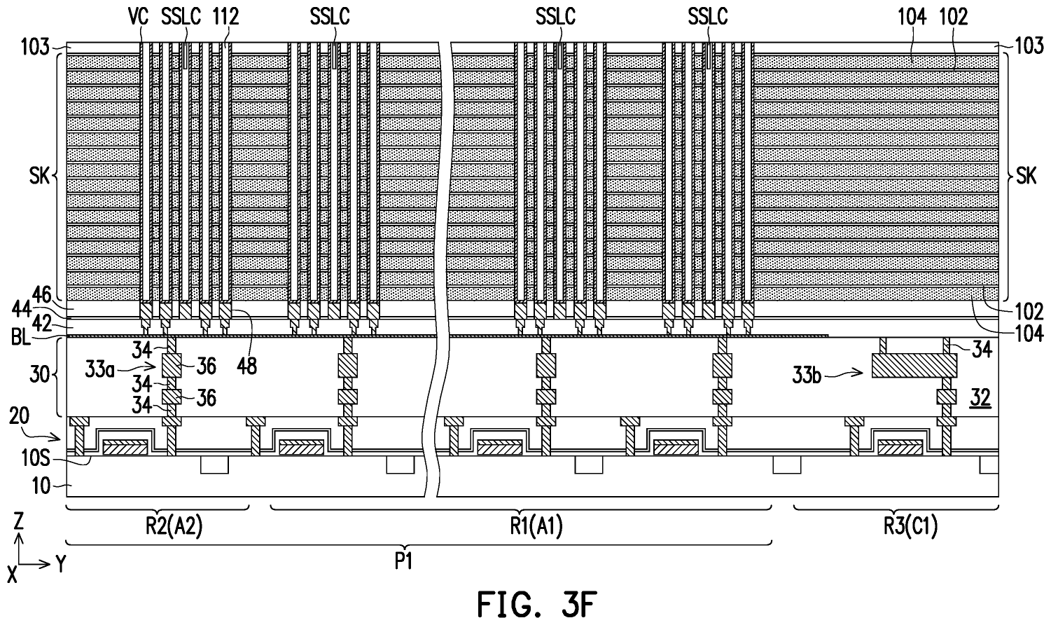

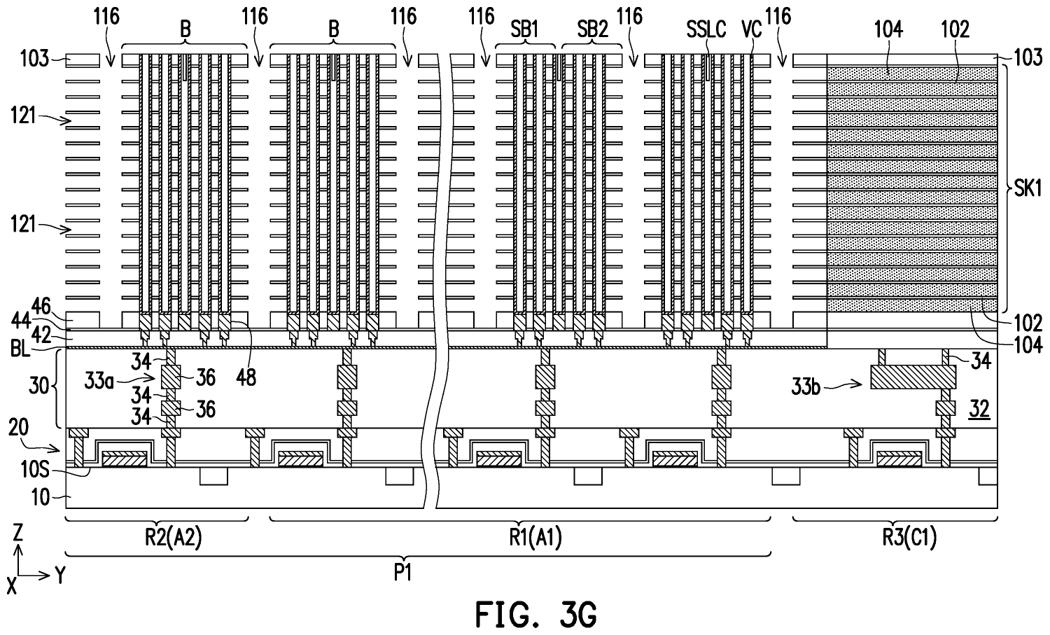

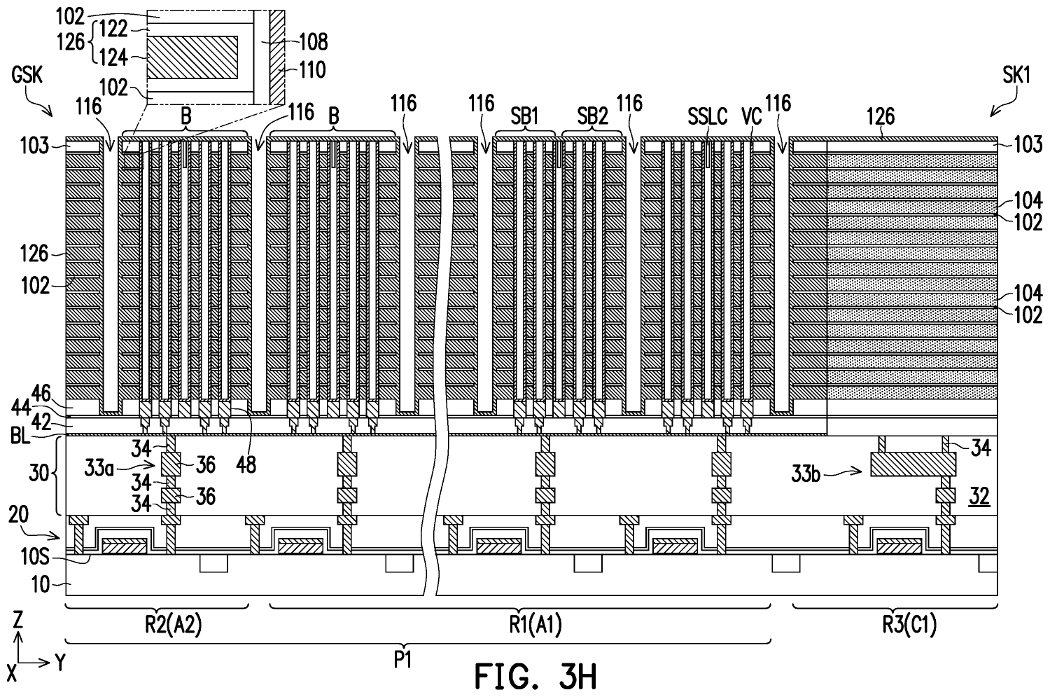

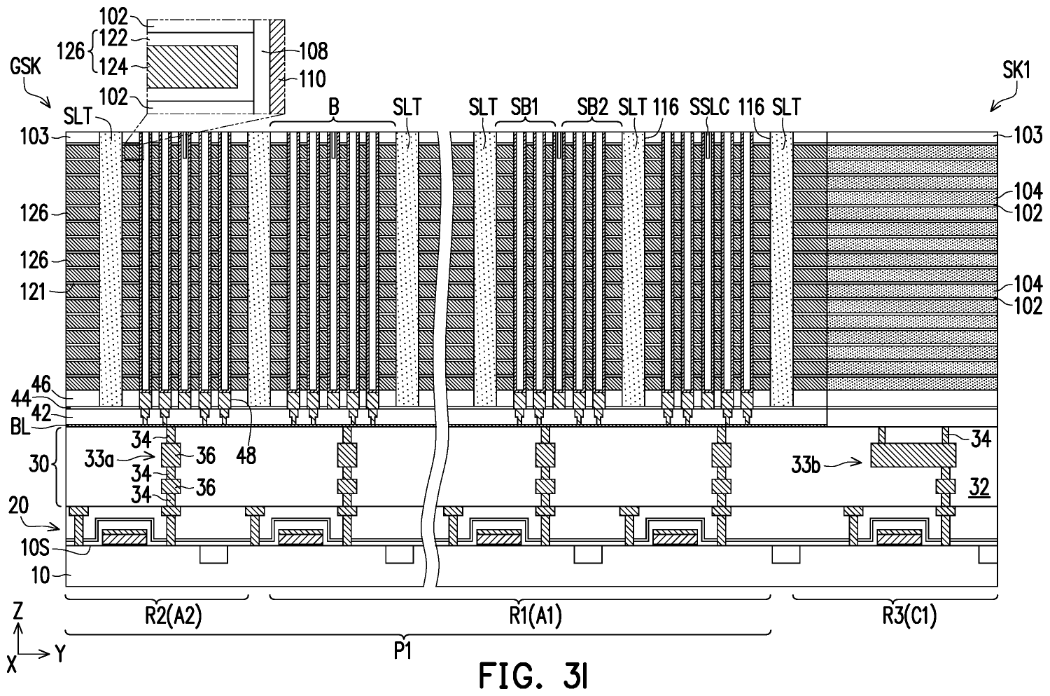

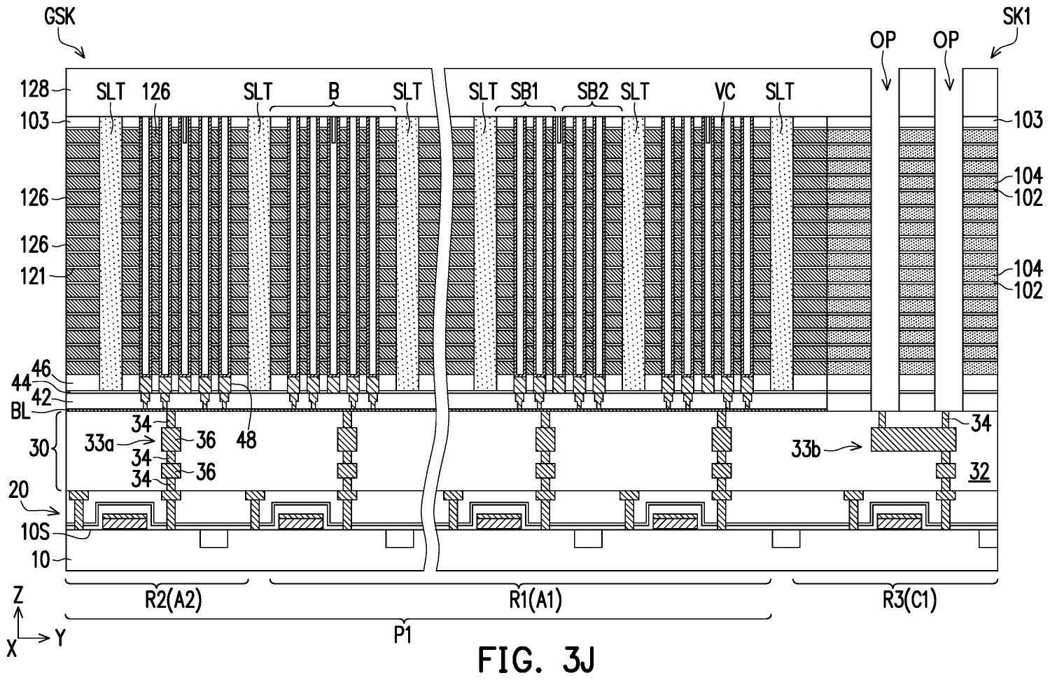

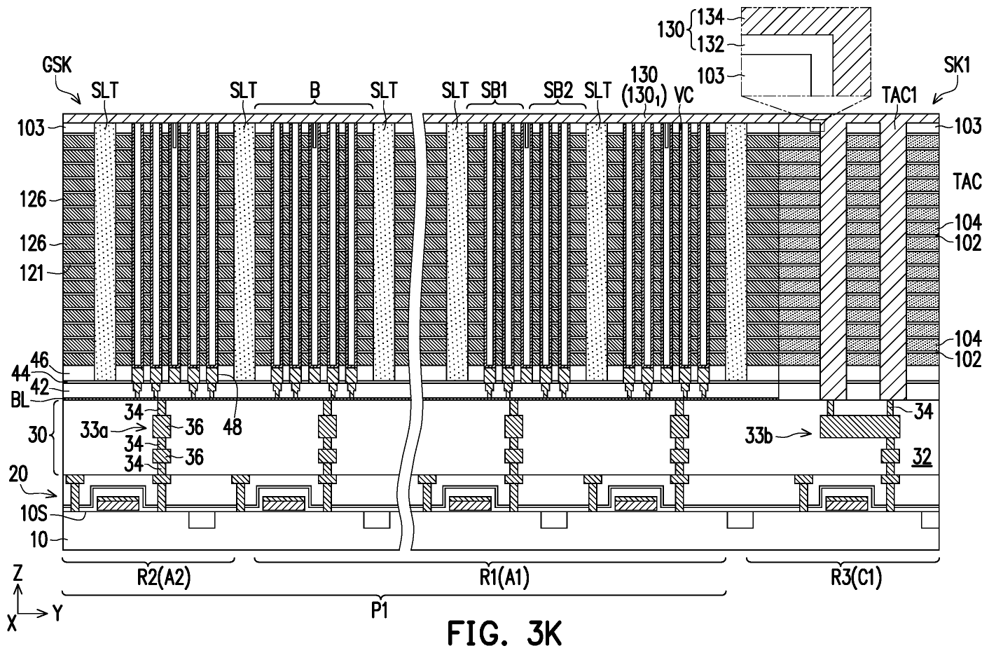

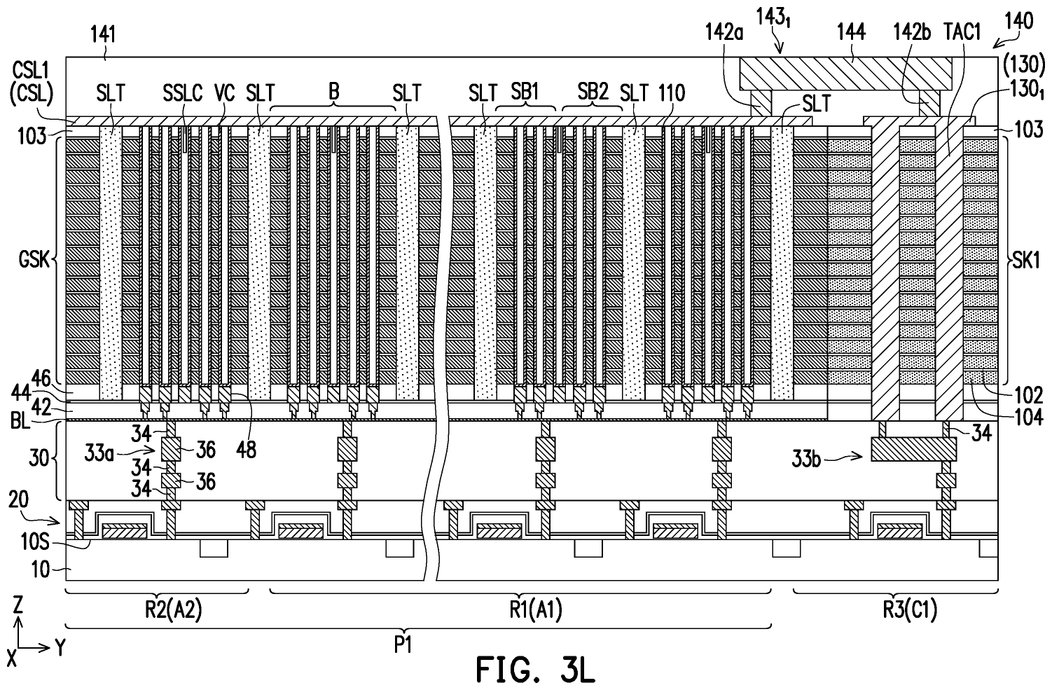

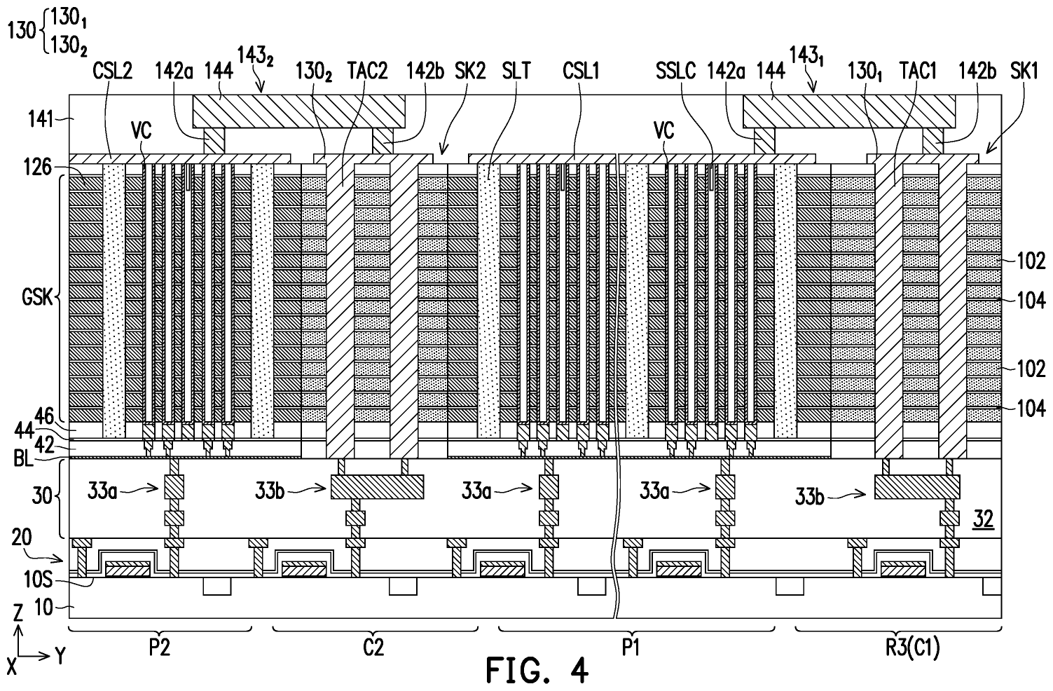

FIG. 1A to FIG. 1C show top views of a plurality of plane regions of a memory device at multiple stages according to an embodiment of the disclosure. FIG. 2A to FIG. 2C show top views of a memory device in a plane region at multiple stages according to an embodiment of the disclosure. FIG. 3L shows a schematic cross-sectional view of a memory device according to an embodiment of the disclosure. FIG. 4 shows another schematic cross-sectional view of the memory device according to an embodiment of the disclosure.

Referring to FIG. 1A and FIG. 2A, a memory device 100 includes a plurality of plane regions P (e.g., P1 to P4). In some embodiments, the plane region P1, the plane region P2, the plane region P3, and the plane region P4 may be referred to as a first plane region, a second plane region, a third plane region and a fourth plane region respectively. Each plane region P includes a plurality of memory array regions A (e.g., A1 to A8), as shown in FIG. 1A. A gate stack structure GSK is provided on each memory array region A, as shown in FIG. 3L or FIG. 4. Gate layers (word lines) of each plane region P (e.g., P1 to P4) are connected to a decoder XDEC (e.g., XDEC1 to XDEC4). The memory device 100 further includes an input/output module 10.

Referring to FIG. 2A, the gate stack structure GSK on each memory array region A is divided into a plurality of blocks B (e.g., B1 and B2) by slits SLT, as shown in FIG. 2A. As an example, FIG. 2A shows that the memory array regions A1 and A2 respectively include two blocks B1 and B2, but the disclosure is not limited thereto. Each block B (e.g., B1) is divided into a plurality of sub-blocks SB (e.g., SB1 and SB2) by a selective source line cut slit SSLC.

A memory cell array MCA is provided in each sub-block SB. The memory cell array MCA is composed of a plurality of rows and a plurality of columns of memory cells MC. A channel pillar VC of the memory cells MC extends through the gate stack structure GSK. In some embodiments as shown in FIG. 3L, the channel pillar VC is perpendicular to a surface 10S of a substrate 10, it may also be referred to as a vertical channel pillar VC.

Referring to FIG. 1B and FIG. 2B, in the embodiment of the disclosure, bit lines BL connected to first ends of the corresponding channel pillars VC are disposed below the gate stack structure GSK and the channel pillars VC. Each plane region P (e.g., P1, P2, P3, or P4) includes a plurality groups of bit lines BL (e.g., BL1, BL2, BL3, or BL4). These bit lines BL in each group extend in the Y direction and are arranged in the X direction. Each bit line BL may be connected to first ends (i.e., bottom ends) of the channel pillars VC of different blocks B. As shown in FIG. 3L or FIG. 4, the bit lines BL may be electrically connected, through a first interconnect structure 30 disposed below the gate stack structure GSK, to a circuit structure 20 disposed below the interconnect structure 30.

Referring to FIG. 1C and FIG. 2C, in the embodiment of the disclosure, a common source plate CSL is disposed above the channel pillars VC, and is connected to second ends (i.e., top ends) of the channel pillars VC. The number of the common source plate CSL is less than the number of bit lines BL in each plane region P. In some embodiments, each plane region P includes only one common source plate CSL, but the disclosure is not limited thereto. The common source plate CSL continuously extends to cover the gate stack structure GSK in the memory array regions A1 to A8, and is electrically connected to the second ends of the channel pillars VC in the memory array regions A1 to A8. The common source plates CSL1 to CSL4 of the plane regions P (e.g., P1 to P4) may be separated from each other.

Referring to FIG. 1C and FIG. 2C, the common source plates CSL1 to CSL4 are respectively electrically connected to the circuit structure 20 (shown in FIG. 3L and FIG. 4) below the gate stack structure GSK. In this embodiment (as shown in FIG. 3L and FIG. 4), the common source plates CSL1 to CSL4 are respectively electrically connected to the circuit structure 20 through an interconnect structure 140 disposed above the common source plates CSL1 to CSL4, through-array contacts TAC (e.g., TAC1) disposed in a contact region C (e.g., C1) outside each plane region P (e.g., P1), and the interconnect structure 30. In some embodiments, the interconnect structure 30 may be referred to as a first interconnect structure, and the interconnect structure 140 may be referred to as a second interconnect structure.

Referring to FIG. 1A, the contact region C (e.g., C1 or C3) is adjacent to the first memory array region A1 of each plane region P (e.g., P1 or P3) and is not adjacent to other memory array regions (e.g., A2 to A7) within the plane region P (e.g., P1 or P3). Alternatively, the contact region C (e.g., C2 or C4) is located between the last memory array region A8 of the plane region P (e.g., P1 or P3) and the first memory array region A1 of the adjacent plane region P (e.g., P2 or P4).

Referring to FIG. 2A, the through-array contact TAC (e.g., TAC1) extends through an insulating stack structure (shown in FIG. 3L and FIG. 4) located in the contact region C.

Referring to FIG. 3L and FIG. 4, the through-array contact TAC1 in the contact region C1 passes through an insulating stack structure SK1, and the through-array contact TAC2 in the contact region C2 passes through an insulating stack structure SK2. The insulating stack structures SK1 and SK2 are formed by alternately stacking a plurality of insulating layers 102 and a plurality of intermediate layers 104 with each other. In some embodiments, the insulating stack structure SK1 may be referred to as a first insulating stack structure, and the insulating stack structure SK2 may be referred to as a second insulating stack structure. In some embodiments, the contact region C1 may be referred to as a first contact region, and the contact region C2 may be referred to as a second contact region.

Referring to FIG. 4, in one example of the disclosure, the through-array contact TAC (e.g., TAC1 and TAC2) is connected to the common source plate CSL (e.g., CSL1 and CSL2). The through-array contact TAC (e.g., TAC1 and TAC2) is not disposed inside the plane region P (e.g., P1 and P2), but is disposed in the insulating stack structure SK1 or SK2 in the contact region C (e.g., C1 and C2) outside the plane region P. The through-array contact TAC (e.g., TAC1 and TAC2) connected to the common source plate CSL (e.g., CSL1 and CSL2) is not further disposed in the slit SLT. Moreover, the bit lines BL may be directly connected to the interconnect structure 30 below. Therefore, similarly, the through-array contact TAC (e.g., TAC1 and TAC2) connected to the bit lines BL (e.g., BL1 and BL2) is not further disposed in the slit SLT. In other words, a through-array contact TAC (e.g., TAC1 and TAC2) connected to the bit line BL is not provided between two adjacent memory array regions A (e.g., A1 and A2) in the plane region P (e.g., P1 and P2), and a through-array contact TAC (e.g., TAC1 and TAC2) connected to the common source plate CSL is not provided between two adjacent memory array regions A (e.g., A1 and A2) in the plane region (e.g., P1 and P2). Since the slit SLT is filled with an insulating material and it is not required to dispose a through-array contact TAC therein, the width of the slit SLT is effectively reduced.

FIG. 3A to FIG. 3L show schematic cross-sectional views of a fabrication process of a memory device according to an embodiment of the disclosure. FIG. 4 shows another cross-sectional view of the memory device according to the embodiment of the disclosure.

Referring to FIG. 3A, a substrate 10 is provided. The substrate 10 may be a semiconductor substrate, such as a silicon-containing substrate. The substrate 10 includes a first region R1, a second region R2, and a third region R3. The first region R1 is located between the second region R2 and the third region R3. The first region R1 is, for example, a topmost memory array region A1 in a first plane region P1 (shown in FIG. 1A). The second region R2 and the third region R3 are located on two sides of the first region R1 and are adjacent to the first region R1. The second region R2 is, for example, a memory array region A2 (shown in FIG. 1A) adjacent to the topmost memory array region A1 in the first plane region P1. Therefore, the first region R1 and the second region R2 may be respectively referred to as a first memory array region and a second memory array region. The third region R3 is, for example, a contact region C1 (shown in FIG. 1A) on the periphery of the first memory array region A1 in the first plane region P1.

Circuit structures 20 are formed on the substrate 10 in the first region R1, the second region R2, and the third region R3. In some embodiments, the circuit structures 20 in the first region R1 is referred to as a first circuit structure 20, the circuit structures 20 in the second region R2 is referred to as a second circuit structure 20, and the circuit structures 20 in the third region R3 is referred to as a third circuit structure 20. The circuit structure 20 may include an active device or a passive device. The active device is, for example, a transistor, a diode, etc. The passive device is, for example, a capacitor, an inductor, etc. The transistor may be an N-type metal-oxide-semiconductor (NMOS) transistor, a P-type metal-oxide-semiconductor (PMOS) transistor, or a complementary metal-oxide-semiconductor (CMOS). In some embodiments, the circuit structure 20 may include a plane-buffer.

An interconnect structure 30 is formed on the circuit structure 20 in the first region R1, the second region R2, and the third region R3. The interconnect structure 30 may include a plurality of dielectric layers 32 and a conductive interconnect 33 (e.g., 33a and 33b) formed in the dielectric layers 32. The conductive interconnect 33 includes a plurality of conductive plugs (also referred to as vias) 34, a plurality of conductive lines 36, etc. At least one of the dielectric layer 32 separates adjacent conductive lines 36. The conductive lines 36 may be connected to each other through the conductive plugs 34, and the conductive lines 36 may be connected to the circuit structure 20 through the conductive plugs 34.

Referring to FIG. 3A again, a plurality of bit lines BL are formed on the interconnect structure 30 in the first region R1 and the second region R2. The bit lines BL extend along the Y direction and are arranged in the X direction as shown in FIG. 2B. The method of forming the bit lines BL includes forming a conductive material layer, such as doped polysilicon, on the interconnect structure 30, and then performing patterning through lithography and etching processes to form a plurality of bit lines BL on the interconnect structure 30 in the first region R1 and the second region R2. The interconnect structure 30 is exposed in the third region R3. The bit lines BL are electrically connected to the circuit structure 20 in the first region R1 and the second region R2 through the conductive interconnect 33a. A memory array will be formed right above the interconnect structure 30 in the first region R1 and the second region R2. The circuit structure 20 is, for example, a complementary metal-oxide-semiconductor (CMOS) formed below the memory array. This architecture may also be referred to as a CMOS-Under-Array (CUA) structure.

Referring to FIG. 3B, a dielectric layer 42 is formed over the substrate 10. The material of the dielectric layer 42 includes silicon oxide, for example. Then, a via hole V3a is first formed in the dielectric layer 42 through lithography and etching processes, and then a via hole V3b is formed in the dielectric layer 42 in the first region R1 and the second region R2 through other lithography and etching processes. Next, a conductive material, such as tungsten, is formed on the dielectric layer 42 and filled in the via hole V3b and the via hole V3a. Afterwards, a planarization process, such as a chemical-mechanical polishing process, is performed to form a via 43b and a via 43a respectively in the via hole V3b and the via hole V3a. Then, a stop layer 44 and a dielectric layer 46 are formed on the dielectric layer 42. The material of the stop layer 44 includes silicon nitride, for example. The material of the dielectric layer 46 includes, for example, a silicon oxide layer. Then, lithography and etching processes are performed to form a via hole V3c exposing the via 43b. Next, a conductive material, such as tungsten, is formed on the dielectric layer 46 and filled in the via hole V3c. Afterwards, a planarization process, such as a chemical-mechanical polishing process, is performed to form a conductive pillar 48 in the via hole V3c. The conductive pillar 48 is electrically connected to the bit line BL through the via 43b and the via 43a.

Referring to FIG. 3C, an insulating stack structure SK is formed over the substrate 10. The insulating stack structure SK includes a plurality of alternating insulating layers 102 and intermediate layers 104. In an embodiment, the material of the insulating layer 102 includes silicon oxide, and the material of the intermediate layer 104 includes silicon nitride. The intermediate layers 104 may serve as sacrificial layers and may be partially removed or completely removed in a subsequent process. Then, the plurality of alternating the intermediate layers 104 and the insulating layers 102 of the insulating stack structure SK in the first region R1 and the second region R2 are patterned to form a staircase structure (not shown). In some embodiments, the staircase structure may be formed through a multi-stage patterning process, but the disclosure is not limited thereto. The patterning process may include processes such as lithography, etching, and trimming.

Referring to FIG. 3D, a dielectric layer (not shown) is formed over the substrate 10 to cover the staircase structure (not shown). An insulating cap layer 103 and a stop layer 105 are formed on the insulating stack structure SK. In an embodiment, the material of the insulating cap layer 103 includes silicon oxide, and the material of the stop layer 105 includes, for example, silicon nitride.

Referring to FIG. 3D, a patterning process is performed to remove part of the stop layer 105, part of the insulating cap layer 103, and part of the insulating stack structure SK in the first region R1 and the second region R2, to form one or more openings 106 passing through the stop layer 105, the insulating cap layer 103, and the insulating stack structure SK. In an embodiment, the opening 106 may have a substantially vertical sidewall, as shown in FIG. 3D. In another embodiment, the opening 106 may have a slightly inclined sidewall (not shown). In an embodiment, the opening 106 is also referred to as a vertical channel opening. In an embodiment, the opening 106 may be formed by a one-stage lithography and etching process. In another embodiment, the opening 106 may be formed by multi-stage lithography and etching processes.

Referring to FIG. 3E, a charge storage structure 108 is formed on the sidewall of the opening 106. The charge storage structure 108 is in contact with the stop layer 105, the insulating cap layer 103, the insulating layers 102, and the intermediate layers 104. The charge storage structure 108 may include a tunneling layer 108₁, a storage layer 108₂, and a blocking layer 108₃. The material of the tunneling layer 108₁ is, for example, silicon oxide. The storage layer 108₂ is, for example, silicon nitride. The blocking layer 108₃ is, for example, silicon oxide or a high dielectric constant material having a dielectric constant greater than or equal to 7, such as aluminum oxide (A1₂O₃), hafnium oxide (HfO₂), lanthanum oxide (La₂O₅), transition metal oxide, lanthanide oxide, or combinations thereof. In an embodiment, the charge storage structure 108 is an oxide/nitride/oxide (ONO) composite layer. The method of forming the charge storage structure 108 includes, for example, an oxide material/nitride material/oxide material (ONO) composite material is deposited. Then, an anisotropic etching process is performed on the (ONO) composite material. Therefore, the charge storage structure 108 is formed on the sidewall of the opening 106 in the form of a spacer and exposes the bottom surface of the opening 106.

Then, referring to FIG. 3E again, a channel pillar VC is formed on the charge storage structure 108. In an embodiment, the material of the channel pillar VC includes polysilicon. The channel pillar VC covers the charge storage structure 108, on a sidewall of the charge storage structure 108 and extends to cover the bottom surface of the opening 106. Since the channel pillar VC extends perpendicular to the surface 10S of the substrate 10, it may also be referred to as a vertical channel pillar.

Next, referring to FIG. 3F, an insulating filling material is formed over the substrate 10 and filled in the opening 106. The insulating filling material includes silicon oxide. Afterwards, a planarization process is performed (e.g., performing a chemical-mechanical planarization process with the stop layer 105 serving as a polishing stop layer) to remove the channel pillar VC and the insulating filling material on the stop layer 105. The insulating filling material remaining in the opening 106 forms an insulating pillar 112. Next, the stop layer 105 is removed.

Then, lithography and etching processes are performed to form a selective source line cut trench, and then an insulating material, such as silicon oxide, is filled in the selective source line cut trench to form a selective source line cut slit SSLC. The selective source line cut slit SSLC extends downward from the surface of the insulating cap layer 103 through several insulating layers 102 and intermediate layers 104 on a top portion of the insulating stack structure SK.

Referring to FIG. 3G, a patterning process is performed on the insulating cap layer 103 and the insulating stack structure SK to form a plurality of trenches 116. The trenches 116 extend in the X direction and pass down in the Z direction through the insulating cap layer 103 and the insulating stack structure SK. In an embodiment, the trench 116 may have a substantially vertical sidewall, as shown in FIG. 3G. In another embodiment, the trench 116 may have a slightly inclined sidewall (not shown). The trench 116 exposes the sidewalls of the insulating cap layer 103, the intermediate layers 104, and the insulating layers 102, and expose the top surface of the stop layer 44. The trenches 116 divide the insulating stack structure SK into a plurality of blocks B (e.g., B1 and B2), and the selective source line cut slit SSLC divides each block B into a plurality of sub-blocks SB1 and SB2.

Referring to FIG. 3G to FIG. 3I, afterwards, a replacement process is performed to replace the intermediate layers 104 in the first region R1 and the second region R2 with conductive layers 126.

First, referring to FIG. 3G, a selective etching process is performed, so that an etchant passes by the trench 116 and etches the intermediate layers 104 on its two sides. Accordingly, the intermediate layers 104 in the first region R1 and the second region R2 are removed to form a plurality of horizontal openings 121. In the first region R1, the horizontal opening 121 exposes part of the charge storage structure 108, the upper and lower surfaces of the insulating layer 102, and the sidewall of the insulating cap layer 103. The selective etching process may be isotropic etching such as a wet etching process. The etchant used in the wet etching process is, for example, a hot phosphoric acid. Through time-mode control of the etching, the intermediate layers 104 in the third region R3 farther from the trench 116 may remain.

Referring to FIG. 3H, then, conductive layers 126 are formed in the trenches 116 and the horizontal openings 121. The conductive layer 126 includes, for example, a barrier layer 122 and a metal layer 124. In an embodiment, the material of the barrier layer 122 includes titanium (Ti), titanium nitride (TiN), tantalum (Ta), tantalum nitride (TaN), or a combination thereof, and the material of the metal layer 124 includes tungsten (W). Part of the intermediate layers 104 in the third region R3 and away from the first region R1 are not replaced with the conductive layers 126. The remaining intermediate layers 104 are still alternately stacked with the insulating layers 102, which is referred to as an insulating stack structure SK1.

Referring to FIG. 3I, then, an etch-back process is performed to remove the conductive layers 126 in the trenches 116. The conductive layers 126 remaining in the horizontal openings 121 may serve as gate layers. The conductive layers 126 in the first plane region P1 may serve as gate layers 126. The gate layers 126 and the insulating layers 102 are alternately stacked with each other to form a gate stack structure GSK. Afterwards, an insulating filling material is formed over the substrate 10 and in the trench 116. Then, a planarization process, such as a chemical-mechanical planarization process, is performed to remove the insulating filling material on the insulating cap layer 103. The insulating filling material remaining in the trench 116 forms a slit SLT. The insulating filling material includes, for example, silicon oxide, silicon nitride, silicon oxynitride, a low dielectric constant dielectric material, or a combination thereof.

Next, referring to FIG. 3J, a hard mask layer 128 is formed over the substrate 10, and lithography and etching processes are performed to form contact openings OP in the insulating stack structure SK1 in the third region R3. The contact opening OP extends from the insulating cap layer 103 and passes through the insulating stack structure SK1 until the interconnect 33b of the interconnect structure 30 is exposed. In this embodiment, in the first plane region P1, the contact opening OP is not formed in the slit SLT in the first region R1, the slit SLT in the second region R2, and the slit SLT between the first region R1 and the second region R2.

Referring to FIG. 3K, the hard mask layer 128 is removed. Next, a conductive layer 130 is formed over the substrate 10 to cover the gate stack structure GSK and the insulating stack structure SK1 and fill in the contact openings OP. The conductive layer 130 includes a barrier layer 132 and a metal layer 134. In an embodiment, the material of the barrier layer 132 includes titanium (Ti), titanium nitride (TiN), tantalum (Ta), tantalum nitride (TaN), or a combination thereof, and the material of the metal layer 134 includes tungsten (W) or copper (Cu). Since, in the first plane region P1, the contact opening OP is not formed in the slit SLT in the first region R1, the slit SLT in the second region R2, and the slit SLT between the first region R1 and the second region R2, the he conductive layer 130 may not filled in these slits SLT.

Referring to FIG. 3L, lithography and etching processes are performed to pattern the conductive layer 130 to form a common source plate CSL1, a conductive line 1301, and a through-array contact TAC1. The through-array contact TAC1 is disposed in the contact region C1 outside the first plane region P1. The conductive layer 130 is further patterned to form a common source plate CSL2, a conductive line 130₂, and a through-array contact TAC2, as shown in FIG. 4. The through-array contact TAC2 is disposed in the contact region C2 between the first plane region P1 and the second plane region P2. In other words, the contact region C2 is outside the first plane region P1 and the second plane region P2.

Still referring to FIG. 3L, the common source plate CSL1 is located on the gate stack structure GSK in the first region R1 and the second region R2 inside the first plane region P1, and is electrically connected to the channel pillars VC. The conductive line 130₁ is located above the insulating stack structure SK1 in the third region R3 (contact region C1) outside the first plane region P1. The through-array contact TAC1 extends through the insulating stack structure SK1, and the through-array contact TAC1 electrically connected to the conductive line 130₁ above and the interconnect 33 below.

Referring to FIG. 4, the common source plate CSL2 is located on the gate stack structure GSK in the second plane region P2 and is electrically connected to the corresponding channel pillars VC. The conductive line 130₂ is located above the insulating stack structure SK2 in the contact region C2 outside the second plane region P2. The through-array contact TAC2 extends through the insulating stack structure SK2, and the through-array contact TAC2 is electrically connected to the conductive line 130₂ above and the interconnect 33 below. Similar to FIG. 3L, the common source plate CSL1 is located on the gate stack structure GSK inside the first plane region P1, and is electrically connected to the corresponding channel pillars VC.

Referring to FIG. 3L and FIG. 4, an interconnect structure 140 is formed on the conductive lines 130₁ and 130₂. The interconnect structure 140 includes a dielectric layer 141 and a plurality of interconnects 143 (e.g., 143₁ and 143₂) located in the dielectric layer 141. Each interconnect 143 includes vias 142a and 142b and a conductive line 144. The via 142a of the interconnect 143₁ is located in the first plane region P1 and is electrically connected to the common source plate CSL1 and the conductive line 144. The via 142b of the interconnect 143₁ is located in the third region R3 (i.e., contact region C1) outside the first plane region P1 and is electrically connected to the conductive line 144 and the conductive line 130₁. In other words, the common source plate CSL1 located in the first plane region P1 is connected to the conductive line 144 through the via 142a located in the first plane region P1, is electrically connected to the via 142b located outside the first plane region P1 through the conductive line 144, and then is electrically connected to the interconnect 33b of the interconnect structure 30 through the conductive line 130₁ and the through-array contact TAC1. In other words, the through-array contact TAC1 is electrically connected to the common source plate CSL1 in the first plane region P1, and is electrically isolated from the second common source plate CSL2. The through-array contact TAC1 is electrically connected to the circuit structure 20 in the first plane region P1. The circuit structure 20 in the first plane region P1 is located between the plurality of bit lines BL and the substrate 10, and electrically connected to the bit lines BL and the first through-array contact TAC1.

Referring to FIG. 4, similarly, the common source plate CSL2 located in the second plane region P2 is connected to the conductive line 144 through the via 142a of the interconnect 143₂ located in the second plane region P2, is electrically connected to the via 142b located outside the second plane region P2 through the conductive line 144, and then is electrically connected to the interconnect 33b of the interconnect structure 30 through the conductive line 130₂ and the through-array contact TAC2. In other words, the through-array contact TAC2 is electrically connected to the common source plate CSL2 in the second plane region P2, and is electrically isolated from the first common source plate CSL1. The through-array contact TAC2 is electrically connected to the circuit structure 20 in the second plane region P2. The circuit structure 20 in the second plane region P2 is located between the plurality of bit lines BL and the substrate 10, and electrically connected to the bit lines BL and the first through-array contact TAC1.

In the embodiment of the disclosure, the common source plate is disposed above the gate stack structure in the plane region. In some embodiments, each plane region is provided with a common source plate to connect to the channel pillars of multiple memory array regions. The through-array contact connecting the common source plate is disposed outside the plane region, and is not disposed in the slit of two adjacent memory array regions in the plane region. Since it is not required to dispose the through-array contact in the slit, the width of the slit can be reduced and the chip area occupied can be reduced.

In addition, in the embodiment of the disclosure, the bit lines are disposed below the gate stack structure and are electrically connected to the interconnect of the interconnect structure below through the conductive pillar and the via. Therefore, the winding can be reduced.

What is claimed is:

1. A three-dimensional flash memory device comprising:
a substrate comprising a first plane region;
a plurality of first memory arrays located in the first plane region;
a plurality of first bit lines located between the plurality of first memory arrays and the substrate and electrically connected to the plurality of first memory arrays;
a first common source plate located above the plurality of first memory arrays and electrically connected to the plurality of first memory arrays; and
a first through-array contact disposed in a first contact region outside the first plane region and electrically connected to the first common source plate.

2. The three-dimensional flash memory device according to claim 1, further comprising:
a plurality of second memory arrays located in a second plane region of the substrate;
a plurality of second bit lines located between the plurality of second memory arrays and the substrate and electrically connected to the plurality of second memory arrays;
a second common source plate located above the plurality of second memory arrays and electrically connected to the plurality of second memory arrays; and
a second through-array contact disposed in a second contact region between the first plane region and the second plane region and electrically connected to the second common source plate.

3. The three-dimensional flash memory device according to claim 2, further comprising:
a first insulating stack structure located in the first contact region, wherein the first through-array contact extends through the first insulating stack structure; and
a second insulating stack structure located in the second contact region, wherein the second through-array contact extends through the second insulating stack structure, and the first insulating stack structure and the second insulating stack structure respectively comprise a
plurality of intermediate layers and a plurality of insulating layers alternately stacked with each other.

4. The three-dimensional flash memory device according to claim 2, wherein the second through-array contact is electrically isolated from the first common source plate.

5. The three-dimensional flash memory device according to claim 2, further comprising:
a first circuit structure located between the plurality of first bit lines and the substrate and electrically connected to the plurality of first bit lines and the first through-array contact; and
a second circuit structure located between the plurality of second bit lines and the substrate and electrically connected to the plurality of second bit lines and the second through-array contact.

6. The three-dimensional flash memory device according to claim 2, further comprising:
a plurality of first slits located between the plurality of first memory arrays; and
a plurality of second slits located between the plurality of second memory arrays, wherein the plurality of first slits and the plurality of second slits are not provided with a through-array contact connected to the plurality of first bit lines or the plurality of second bit lines, and are not provided with a through-array contact connected to the first common source plate or the second common source plate.

7. The three-dimensional flash memory device according to claim 2, wherein the first plane region and the second plane region are not provided with a through-array contact connected to the plurality of first bit lines or the plurality of second bit lines, and are not provided with a through-array contact connected to the first common source plate or the second common source plate.

8. A three-dimensional flash memory device comprising:
a substrate comprising a plane region and a contact region, wherein the plane region comprises a plurality of memory array regions, and the contact region is located outside the plane region and is adjacent to the plane region;
a circuit structure located on the substrate;
a gate stack structure located above the circuit structure in the plane region, wherein the gate stack structure comprises a plurality of gate layers and a plurality of insulating layers alternately stacked with each other;
a plurality of channel pillars extending through the gate stack structure;
a plurality of charge storage structures located between the plurality of gate layers and the plurality of channel pillars;
a plurality of bit lines located below the gate stack structure and electrically connected to bottoms of the plurality of channel pillars and the circuit structure;
a common source plate located above the gate stack structure and electrically connected to a plurality of top surfaces of the plurality of channel pillars located in the plurality of memory array regions; and
a through-array contact disposed in the contact region and electrically connected to the common source plate and the circuit structure.

9. The three-dimensional flash memory device according to claim 8, further comprising an insulating stack structure located above the circuit structure in the contact region, wherein the insulating stack structure comprises a plurality of intermediate layers and a plurality of insulating layers alternately stacked with each other, and the through-array contact extends through the insulating stack structure.

10. The three-dimensional flash memory device according to claim 8, further comprising:
a first interconnect structure located between the plurality of bit lines and the circuit structure and electrically connected to the plurality of bit lines and the circuit structure; and
a second interconnect structure located above the common source plate and electrically connected to the common source plate and the through-array contact.

11. The three-dimensional flash memory device according to claim 8, wherein a through-array contact connected to the bit line is not provided between two adjacent memory array regions in the plane region, and a through-array contact connected to the common source plate is not provided between two adjacent memory array regions in the plane region.

12. The three-dimensional flash memory device according to claim 11, further comprising:
a plurality of first slits, each of which is located between the two adjacent memory array regions, wherein the plurality of first slits are not provided with a through-array contact.

13. The three-dimensional flash memory device according to claim 12, further comprising:
a plurality of second slits located in each of the memory array regions and dividing each of the memory array regions into a plurality of blocks, wherein the plurality of second slits are not provided with a through-array contact.

14. The three-dimensional flash memory device according to claim 8, wherein the contact region is adjacent to an end memory array region of the plane region and is not adjacent to other memory array regions within the plane region.

15. A method of fabricating a three-dimensional flash memory device, comprising:
providing a substrate comprising a plane region and a contact region, wherein the plane region comprises a plurality of memory array regions, and the contact region is located outside the plane region and is adjacent to the plane region;
forming a circuit structure on the substrate;
forming a plurality of bit lines located above the circuit structure and electrically connected to the circuit structure;
forming a plurality of memory arrays located on the plurality of bit lines in the plurality of memory array regions and electrically connected to the plurality of bit lines;
forming a common source plate located above the plurality of memory arrays and electrically connected to the plurality of memory arrays; and
forming a through-array contact located in the contact region and electrically connected to the common source plate and the circuit structure.

16. The method of fabricating a three-dimensional flash memory device according to claim 15, wherein formation of the plurality of memory arrays comprises:
forming an insulating stack structure on the circuit structure, the insulating stack structure comprising a plurality of intermediate layers and a plurality of insulating layers alternately stacked with each other;
forming a plurality of channel pillars extending through the insulating stack structure and electrically connected to the bit line and the circuit structure;
forming a plurality of charge storage structures between the plurality of channel pillars and the insulating stack structure;
forming a trench extending through the insulating stack structure;
performing a replacement process to replace the plurality of intermediate layers of the insulating stack structure in the plurality of memory array regions with a plurality of gate layers to form a gate stack structure; and
filling the trench with an insulating material to form a slit.

17. The method of fabricating a three-dimensional flash memory device according to claim 16, wherein the slit is not formed with a through-array contact connected to the plurality of bit lines or connected to the common source plate.

18. The method of fabricating a three-dimensional flash memory device according to claim 16, wherein the slit is not filled with a conductive material.

19. The method of fabricating a three-dimensional flash memory device according to claim 16, wherein the insulating stack structure in the contact region is retained, and the through-array contact extends through the insulating stack structure in the contact region.

20. The method of fabricating a three-dimensional flash memory device according to claim 16, further including:
forming a first interconnect structure between the plurality of bit lines and the circuit structure to electrically connect the plurality of bit lines and the circuit structure; and
forming a second interconnect structure above the common source plate to electrically connect the common source plate and the through-array contact.
